(19) United States
(12) Patent Application Publication
(10) Pub. No.: US 2007/0272290 A1
(43) Pub. Date: Nov. 29, 2007

(54) REGULATING VEHICLE CABIN ENVIRONMENT AND GENERATING SUPPLEMENTAL ELECTRICAL CURRENT FROM WASTE HEAT

(76) Inventors: Joseph Paul Sims, Greeneville, TN (US); Martin P. Eason, Johnson City, TN (US); William K. Hemphill, Johnson City, TN (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/753,187

(22) Filed: May 24, 2007

Related U.S. Application Data
(60) Provisional application No. 60/802,905, filed on May 24, 2006.

(51) Int. Cl. H01L 35/34; H01L 35/28; H01L 35/30

(52) U.S. Cl. 136/201; 136/203; 136/205

(57) ABSTRACT

A method and system for environmental control and supplementary power generation in conventional and hybrid vehicle applications is presented. A thermoelectric heat pump function regulates vehicular interior temperature environments and uses the waste heat from a vehicles engine to power thermocouples and generate supplemental electrical current to power electrical devices. Thermocouples are used to gauge changes in temperature. The Peltier Effect is used to provide both primary cabin environmental control and supplementary power generation for motorized vehicle applications. Thermoelectric generators can be used for both primary internal climate control and supplementary power generation in the vehicular environment. Thermoelectric heat pumps' special characteristics are used to provide (a) primary cabin environment control including cooling, heating, dehumidifying, defrosting, pre-heating/pre-cooling and (b) supplemental DC power generation functions for conventional fossil fueled and/or biomass-fueled vehicles as well as emerging hybrid or all electric vehicle applications.

### CROSS-REFERENCE TO RELATED APPLICATIONS

This application claims the benefit of U.S. Provisional Application Ser. No. 60/802,905, filed May 24, 2006.

### BACKGROUND OF THE INVENTION

The present invention relates to generally to a method and system for primary vehicular cabin environmental control and supplemental vehicular electrical current generation and, in particular, relates to the use of thermoelectric generator arrays to regulate automotive cabin environment and to utilizing operational or residual waste heat from the engine as a source of supplemental power.

With the today's ever increasing need for a reduction in the consumption of fossil fuels as well as a need in the reduction of total pollutants, the method and system outlined here provides considerable benefits in these two critical areas. There is also a greater effort being made to improve the fuel efficiency of internal combustion engines. This can be achieved by decreasing the horsepower drain on the engine as well as lowering the weight of the automobile. In current automobile models, current is drawn from an alternator powered by the engine. The greater the power required, the greater the power drain on the engine. Additionally, internal temperature environment is typically controlled by way of a vapor coolant compressor powered by the engine to cool the compartment and a heater coil that uses heated engine coolant to heat the internal cabin and defrost windshields and side windows. Both devices act to lower fuel efficiency and require significant mechanical systems to provide the intended function. In the former, significant power is drained from the engine to power the compressor, and in the latter, the increased weight of the coil and the additional coolant, such as antifreeze, required to flow to heat the compartment contribute to automobile weight. Moreover, the need to use the vapor coolant in the cooling system contributes to environmental pollution due to its effects on planetary atmosphere.

In 1826, Seebeck discovered that current will flow in a circuit that is comprised of two metallic conductors of different materials if the temperature of the two junctions are different. The electromotive force (e.m.f.) of the circuit is dependent on the thermal conditions. The combination of these materials in a circuit is called a thermocouple. The electromotive force developed by this temperature difference of the two junctions produces a current in a circuit which can be measured and used. The first experimental observation of this was made by Peltier. The quantity of Peltier heat is proportional to the quantity of charge which crosses the junction. It also depends on the material being used and the temperatures of the junction. When current flows in a thermocouple circuit due to a temperature difference of the junctions, heat is absorbed on the high side and ejected at the low side. The difference between the amount absorbed and ejected is converted into electrical energy by the thermocouple. Peltier heat is reversible if a reverse current is forced through the thermocouple by means of an external e.m.f. that is then absorbed and ejected at opposite ends. This design in effect becomes a thermoelectric heat pump or a thermoelectric generator.

By stacking or making an array of thermocouples, a thermopile can be constructed capable of generating large amounts of power in the presence of a temperature differential as seen in the difference between the exhaust of an automobile engine and the ambient atmosphere. The output from a thermoelectric generator can be directly converted and conditioned to provide power to any DC device. By delivering current to the thermoelectric generator, it can be heated or cooled. Additionally, by directing airflow over the thermoelectric generator, it can be used to heat or cool the vehicle's interior cabin space. By using thermoelectric generators as a secondary power source driven by the waste heat from the exhaust to generate current, less current is required from the alternator. With less current drawn from the alternator, there is a decreased power drain on the engine. Moreover, because interior environment temperature can be controlled using thermocouples, the requirement for a compressor or heater coil is no longer necessary.

Peiffer et al (U.S. Pat. No. 5,901,572) discloses one approach known for heating and cooling the interior space of a vehicle employs the use of thermoelectric generators in motor vehicles for auxiliary heating and cooling. Peiffer disclose a use of “thermo-electric coolers” in conjunction with a pair of forced air heat exchangers and panels or containers of sorbent materials for energy storage to heat or cool a motor vehicle. A stated object of Peiffer is to provide relatively low power auxiliary heating and air conditioning for regulating the temperature if a vehicle's interior space, such as a tractor trailer's sleeping compartment, when the vehicle is shut down. The use of thermal energy absorbing materials allows the device in Peiffer to use the vehicle's existing heating and cooling systems to generate, capture and store thermal energy during periods of normal engine operation and then distribute the stored thermal energy in a regulated manner in conjunction with the use of additional air warming or cooling devices. Thus, the thermal storage and temperature regulation system of Peiffer is only directed to providing extended, but nevertheless temporary, periods of heating and cooling while the vehicle's primary power plant is not operating. Additionally, Peiffer only addresses nominal interior temperature regulation and not critical elements of primary interior cabin environment control including humidity control and government-mandated minimums for windshield/window defrosting.

Another approach known for regulating the environment of a vehicle's cabin interior in order to pre-heat or cool the cabin interior prior to normal engine start-up and operation is to use a thermal storage reservoir as disclosed in Carr (U.S. Pat. No. 5,277,038). A stated objection of Carr is to provide additional cooling and/or heating from a thermal storage system and to release the cooling or heating at a desired time, such as prior to entering the vehicle or during vehicle startup. Thus, the thermal storage system in Carr is directed to only providing heating and cooling for generally short periods of time and does not address the critical elements of primary interior cabin environment control including humidity control and government-mandated minimums for windshield/window defrosting.

Other devices have also been proposed to control internal automobile cabin thermal environments such as, for example, Shikata et al (U.S. Pat. No. 6,213,198). Shikata discloses affecting temperature regulation by either turning a thermocouple element array fully on or fully off. Changes in temperature are altered by varying airflow across the thermocouple. Shikata does not offer individual control of the array elements to regulate exhausted air or provide for defrost or dehumidification functions. In addition, myriad patent applications have also proposed devices to affect the same function using thermocouples such as Ito et al (U.S. Publication No. 2005/0067158) and Krupp et al (U.S. Publication No. 2004/0065101).

However, there is a need to increase fuel efficiency by lowering power drain on the alternator by negating the need for a vapor coolant compressor. Additionally, by obviating the need for a heater coil, additional engine coolant, and air conditioning components, automobile weight is reduced and maintenance costs are decreased.

There is also a need to control the vehicle's cabin environment with both the engine on and off and a need to warm the engine block in cold weather.

There is another need for a source of supplementary current to power automobile electrical components, reduce alternator loading, and battery charging.

There is also the need to provide climate control for electrically driven vehicles wherein the system can be used to reduce weight and eliminate the need for environmental control using compressor type systems and heater coils.

### BRIEF SUMMARY OF THE INVENTION

According to the present invention, thermocouples can be used to gauge changes in temperature. The Peltier Effect is then employed to provide both primary cabin environmental control and supplementary power generation for motorized vehicle applications. Thermoelectric generators can be used for both primary internal climate control and supplementary power generation in the vehicular environment. The thermoelectric generators' special characteristics are used to provide (a) primary cabin environment control including cooling, heating, dehumidifying, defrosting and (b) supplemental DC power generation functions for conventional fossil fueled and/or biomass-fueled vehicles as well as emerging hybrid or all electric vehicle applications.

In accordance with one embodiment of the present invention, a thermoelectric generator is used to regulate vehicular interior environments.

In accordance with another embodiment of the present invention, a thermoelectric generator uses the waste heat from a vehicle's engine to power thermocouples and generate supplemental electrical current to power electrical devices.

Accordingly, it is a feature of the embodiments of the present invention to simplify the system for regulating and controlling vehicle cabin environment.

It is another feature of the embodiments of the present invention to decrease fuel utilization and weight reduction, thereby increasing fuel economy.

It is still another feature of the embodiments of the present invention to control the temperature within the vehicle cabin while the engine is off.

It is yet another feature of the embodiments of the present invention to provide supplementary current to power automobile electrical components, thereby reducing alternator loading and provide battery charging. The supplementary power can also be used, in cold weather, to heat the engine block.

It is still yet another feature of the embodiments of the present invention to no longer require heavy, mechanically driven HVAC elements which contain potentially harmful fluids, thereby decreasing air and source pollutants as well as maintenance costs. Other features of the embodiments of the present invention will be apparent in light of the description of the invention embodied herein.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 is a schematic of a cabin environmental control module according to an embodiment of the present invention.

FIG. 2 is a schematic of a cabin environmental control module thermoelectric generator element state control according to an embodiment of the present invention.

FIG. 3 is a schematic of a power conditioner and controller system according to an embodiment of the present invention.

FIG. 4 is a schematic of a cabin environmental controller and power conditioner and controller system relationship according to an embodiment of the present invention.

FIG. 5 is a schematic of an embodiment of the power conditioner and controller system according to an embodiment of the present invention.

### DETAILED DESCRIPTION

In the following detailed description of the embodiments, reference is made to the accompanying drawings that form a part hereof, and in which are shown by way of illustration, and by way of limitation, specific embodiments in which the invention may be practiced. It is to be understood that other embodiments may be utilized and that logical, mechanical and electrical changes may be made without departing from the spirit and scope of the present invention.

Overview

The present invention is directed to environmental control and supplementary power generation in conventional and hybrid vehicle applications. Technical considerations are those related to temperature regulation of the interior automobile cabin and supplemental power generated by waste heat from the exhaust. The invention is a system design that uses a thermoelectric heat pump function to regulate vehicular interior temperature environments and also uses the waste heat from a vehicles engine to power thermocouples and generate supplemental electrical current to power electrical devices. This system will utilize the heat pump characteristics of the thermoelectric generator to provide heating or cooling of circulated air.

Defrost/Humidity Control capabilities with moisture extraction can be employed by using some of the thermopiles in the environmental control to cool (moisture extraction) and other thermopiles to heat, thus providing a similar function to that of existing automobile defroster systems. Current for the environmental control system will be drawn from the vehicle electrical bus, or in the case of the battery powered hybrid vehicle, it could be taken from the main drive battery. Additionally, the environmental system can be powered by accessory power sources that provide current without the engine being on (e.g. solar panel, external electrical hookup, battery).

The second part of the system design is composed of an array of thermoelectric generators attached to the exhaust components of an engine. The array will generate current, which is delivered to the vehicle electrical bus. The use of this type of thermoelectric generator, or heat pump, system offers distinct advantages over present vehicle interior environment control technology.

One system advantage is system simplification. This system obviates the need for a coolant compressor with its driving belts as well as a heater coil. Because the system uses thermoelectric heat pumps or generator arrays, there are significantly fewer moving parts. A simplified system also decreases maintenance costs. Because the system is significantly simplified and has very few mechanical parts, the maintenance cost of the cabin environmental control system is reduced.

Other system advantages are weight reduction, increased fuel economy and decreased environmental harm. The removal of a compressor, the heater coil, and the reduction in engine coolant volume (less coolant is required as the heater coil is no longer present), will reduce the automobile weight. With decreased power drain on the engine from the compressor and alternator as well as the weight reduction, fuel efficiency from the engine will improve. Because there is no need for a compressor, there is no longer a requirement for vapor coolant (e.g. Freon), thereby, decreasing environmental harm.

Still more system advantages are environmental control, temperature control with the engine off and off-line engine warming, in cold weather. The amount of heat energy developed is directly related to supplied current so rapid heating or cooling of the cabin interior is possible by controlling the amount of applied current. Because the thermoelectric devices' heat pump aspect means that the thermopile can be powered by either an internally or externally supplied power source, the interior compartment temperature can be controlled with the engine off. This allows the operator to keep the car heated or cooled while the car is not occupied. The supplemental power generation array mounted to the exhaust stack can also be used to heat the engine block by driving current through the thermoelectric generator array or through similar thermoelectric heat pump devices placed on or within the engine

Finally, there is the system advantage of a source of supplementary power. The design provides supplementary current to power automobile electrical components, reduce alternator loading, and battery charging including the thermopiles used for environmental control. Although the power generated from the waste heat of the engine is not sufficient to provide all the power required to drive the environmental thermoelectric array, it does provide a continuous secondary source of electrical power with no additional drain on the engine. Also, each vehicle will have a different exhaust configuration, thus a different capability to generate power. However, the capability to generate over 1,000 watts of power has been found thus eliminating the need for an alternator.

The elementary building block of the system is the Thermoelectric Generator (TEG) element. The TEG element is a single Peltier Effect assembly and comprising an array of electrically connected thermocouples embedded in a thermally conductive and electrically insulated matrix. The TEG element has two thermally conductive surfaces thermally isolated from each other and two electrically conductive wires suitable for transferring electric current into the thermocouple array (for generating a temperature difference between the two surfaces (i.e., a COLD side and a HOT side) in proportion to an applied differential voltage that may or may not be capable of being reversed) or out of the thermocouple array (in proportion to the temperature difference of the two surfaces). To facilitate the rate of heat transferred between the TEG's thermally conductive surface and the air or other fluid, a plurality of mechanical heat sink devices each with an array of pins, fins, or other large surface areas will be used; operationally, theses heat sinks may be considered to be part of the TEG element.

A single TEG element, or a plurality of TEG elements, in electrical contact and physically located in a contiguous manner wherein either the single TEG element or the plurality of TEG elements can be controlled as a discrete init is a TEG array. The TEG elements composing the TEG array may also be stacked in a three-dimensional configuration. A TEG array element is a discrete TEG element of a TEG array or an electrically connected, contiguous group of arrayed TEG elements in a two-dimensional or three-dimensional configuration that, for the purposes of control and electrical connectivity, can be treated as one discrete unit. From a control and operational perspective, a TEG Array Element can be viewed as a single, operational TEG element.

A stacked TEG array is a plurality of TEG elements in electrical contact and physically located in a contiguous, three-dimensional configuration with the COLD surface of one TEG element in direct or very close proximal contact (i.e., separated by a thin, thermally conductive film) with the corresponding HOT surface of an adjoining TEG element and electrically connected in such a manner as to increase the ultimate temperature difference between the array's outermost COLD and HOT surfaces; wherein the TEG elements stacked in this back-to-front configuration provide a higher differential temperature between the outermost surfaces than one TEG element alone.

Cabin Environment Controller (CEC)

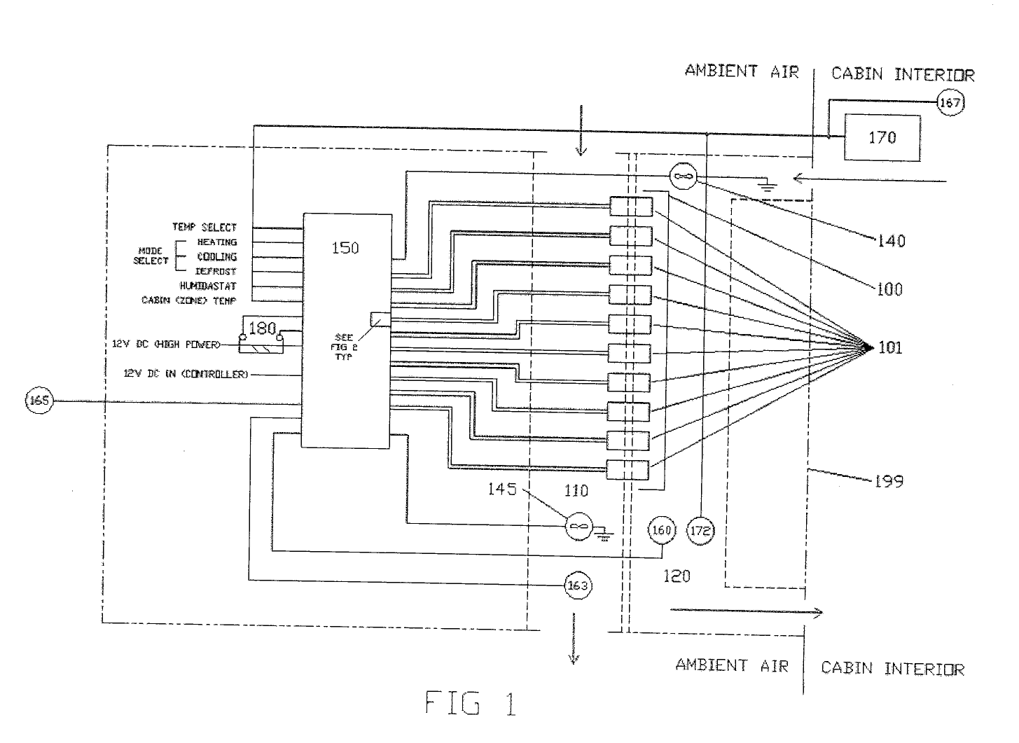

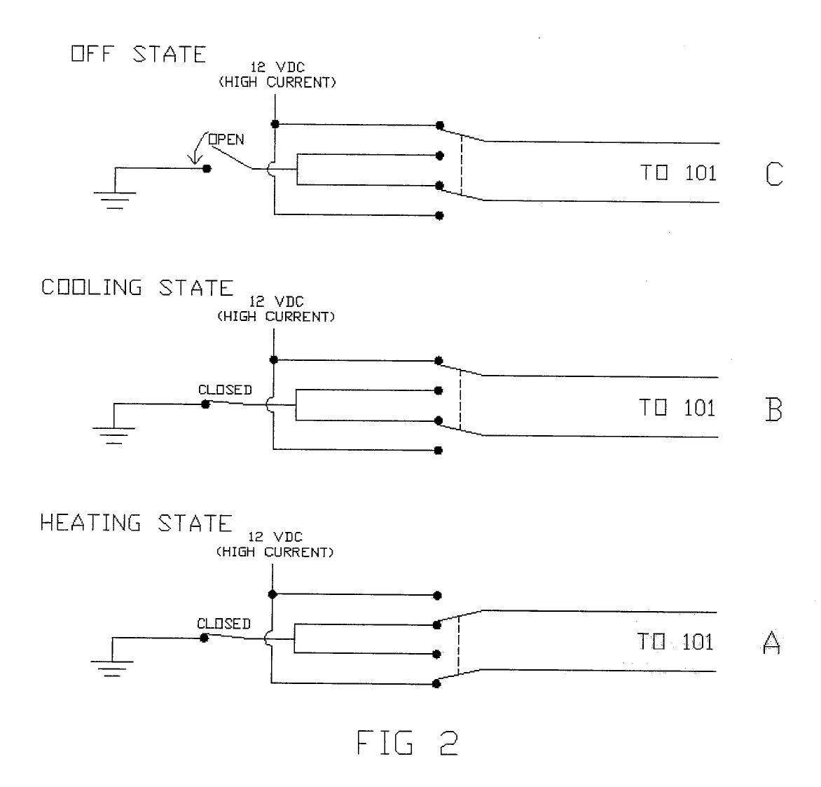

The regulation of cabin environmental functions are shown in FIGS. 1 and 2 and can be employed regardless of the implementation of the power generation functions. Referring to FIG. 1, one embodiment of a Thermoelectric Generator Environmental Control Module (TEG-ECM) Assembly 199 is illustrated in a heating configuration. The TEG-ECM 199 can be a discrete, possibly modular, collection of one or more TEG operational elements 101 or TEG arrays 100, internal (HOT) and external (COLD) side plena 110, 120, sensors, flow control, and communication devices 170 capable of conditioning air (e.g., heating, cooling, and/or dehumidifying) and controlling the distribution of one or more flows of conditioned air. The TEG Array 100 can be made up of at least one TEG element (i.e., a single TEG element or TEG Array elements) 101. Each TEG operational element 101 can be capable of heating and cooling and can be tied individually to a microcontroller 150. An air mover (e.g., a fan or blower) 140 can be used to direct air from the cabin over the TEG array 100 in the interior plenum 120. A second air mover 145 can be used to direct air from the exterior over the TEG array 100 in the exterior plenum 110. Sensors 160, 163, 165 for the air temperatures of the interior plenum, exterior plenum and outside (ambient) can be used as controls. An additional temperature sensor 167 can monitor temperature within the cabin or a particular zone of the cabin. Additional temperature sensors can be added for each potential control zone within the cabin. Cabin flow and temperature control 170 can have a temperature select to set the temperature for the cabin. A humidistat 172 can be mounted in interior plenum 120. A shunt 180 can be used to monitor collective TEG elements 101 current loading for failure detection.

As shown in FIG. 1, the two sides 110, 120 of the thermoelectric array 100 are thermally isolated. One side can be mounted in a plenum 110 so external, or ambient, air can be directed over the TEG array 100 and the other side can be mounted such that another plenum 120 can be used to move cabin air over the other side of the TEG array 100. These two plenums are thermally isolated. A microcontroller 150 can be used to select modes of operation, control power application, and monitor system sensors 160, 163, 165, 167, 172 and operate air movers 140, 145. Additional TEG-ECM assemblies 199 can be deployed throughout the cabin as needed.

FIG. 2 illustrates a schematic of the individual cabin environmental control module TEG operational element 101 state control. As shown in FIG. 2, the individual TEG operational elements 101 can be wired such that the microcontroller 150 can set each individual TEG operational element to heat (FIG. 2A), to cool (FIG. 2B), or to turn off (FIG. 2C). This arrangement will also allow the controller 150 to have the capability to vary the number of active TEG operational elements 101, depending on temperature regulatory requirements; thus maximizing efficiency and reducing power loading. The ability to control each TEG operational element 101 individually allows each environmental zone in the vehicle cabin to be independently controlled either at a main control panel or via a remote control device.

Individual TEG elements 101 can have the capability of generating a no-load temperature differential of approximately 67° C. As material technologies change, this temperature differential may increase or the overall efficiency of the TEG components may increase. This unique heat pump function can be employed to both cool and heat the vehicle cabin. Because the TEG-ECM Microcontroller 150 can vary the number of TEG operational elements 101 within a TEG array 100 that are turned on or off, a more precise regulation of temperature change is possible. Additionally, TEG power consumption can be controlled, monitored and actively regulated more efficiently by controlling the number of active TEG elements 101, especially during periods of engine shutdown, and monitoring overall TEG-ECM current draw via the shunt(s) 180.

Government regulations identify the minimum performance specification for defroster function. In the U.S., the regulation is FMVSS 103 (Federal Motor Vehicle System Standard 103) and in the European Union, it is EEC Directive 78/317. Currently, these are the only regulations which apply to automobile-vehicle-heating and cooling systems. Using the TEG array 100, the extraction of moisture can be obtained by having at least one of the TEG operational elements 101 in the arrayed 100 set to cool thus condensing the moisture and the other TEG operational elements 101 set to heat thus providing a defroster function similar to that of existing vehicular systems. This system, thereby, provides a simplified method to dehumidify the air without using additional heat sources.

An example of the time and energy involved in changing the temperature inside a vehicle with 85.5 cu.ft. of interior space is now discussed. Assuming a Mini SUV cabin volume of 85.5 cu.ft. or 2.42 m³, 3° C. temp change, a single TEG operational element developing 180 BTU or 52 watts of power (heat flow rate), specific heat of air 1004 J/kg-K and air density of 1.2 kg/m³, an TEG array 100 of ten TEG operational elements 101 will be needed. Though the power loading would be very high, the alternator system could supply the load and a 3° C. change would require 56.725 seconds. However, the temperature transfer is by convection so given a forced convection value of 50 W/(m²K) for a heat transfer coefficient will require a surface area 0.34 M² of with a surface temp of 303 Kelvin and 0.69 m² with a 25 W/(m²K) heat transfer rate.

Power Conditioner and Controller (PCC) System

TEG Supplemental Power Array (TEG-SPA) is a plurality of TEG elements in electrical contact and physically located in a two-dimensional or three-dimensional contiguous manner with one surface (the HOT side) affixed in direct or proximal contact with a vehicular component providing a source of heat (including, but not limited to, an engine block or casing, exhaust manifold, exhaust pipe, oil pan, radiator, acoustic muffling device, fuel cell enclosure, casing, body panel, and ambient air); the other surface (the COLD side) thermally isolated from the HOT side and in thermal communication with a heat sink (including but not limited to ambient air, engine coolant, or a flowing or expanding fuel source wherein the heat source and heat sink are of a suitable temperature difference to cause an electrical current to be generated by one or more of the TEG elements that compose the array.

This system can harvest waste heat produced by the engine, or any other temperature differential producing device, during operation to generate supplemental current to power environmental control modules and other accessory devices. Even though the system does not provide enough current to operate the internal environmental control modules, it allows for a significant decrease in power draw from the alternator and engine. Moreover, because an engine continues to stay hot after shutdown, the supplementary power generation can continue to provide electrical current even after the engine is turned off. Additionally, when the internal environmental control modules are not in use, the excess current generated can be used as a source for supplementary power for accessories and/or battery recharging.

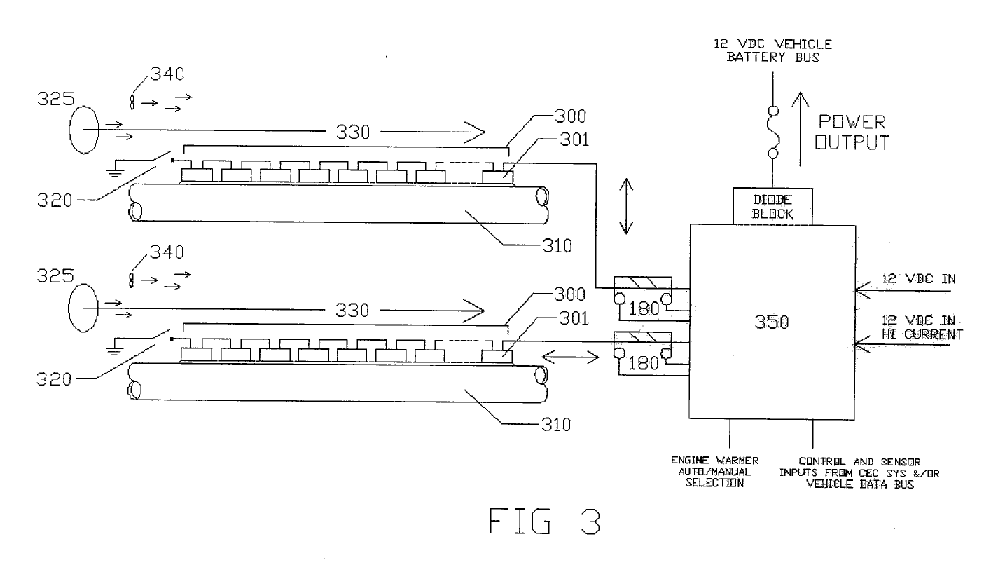

Referring to FIG. 3, in one embodiment, the exhaust TEG element arrays 300, each comprised of at least one high-temperature TEG operational element 301, can be mounted on engine exhausts 310. An air inlet 325 draws in air which can be forced across the HOT side 330 of the exhaust TEG element array 300 by an air mover (e.g., a blower) 340. Relays 320 to each exhaust TEG array 300 can be controlled by a Power Conditioner and Controller (PCC) microcontroller 350. Each high-temperature TEG operational element 301 in the array 300 can yield 2.38 V_{DC} at 8 amps. Under ideal conditions, a maximum power generation can equal 16.6 V_{DC} at 16 amps. The number of high-temperature TEG operational elements 301 changes as a function of demand and/or available mounting area on the engine exhaust 310. Thermal isolation exists between the exhaust component mounted (HOT) side 310 and the forced air (COLD) side 330.

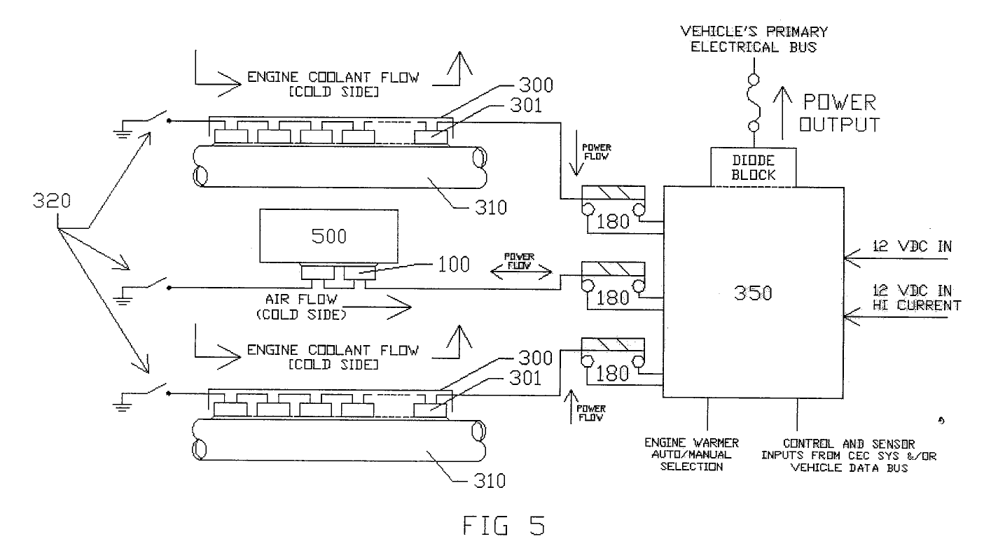

Referring to FIG. 5, another embodiment of the exhaust TEG array 300 is illustrated where the TEG array 300 is mounted to the engine exhaust 310 to warm the engine block 500 during cold winter temperatures. By using the PCC controller 350 to drive current through the exhaust TEG array 300, heat can be generated and transferred to the engine block 500. The TEG arrays 300 can be stacked. The HOT and COLD sides of each high-temperature TEG element 301 are thermally isolated. Alternatively, each stacked exhaust TEG array 300 is thermally isolated. The current can be from a battery or a conditioned external alternating current (AC) sources. Input power from each TEG array 300 can be measured using a shunt 180.

Overall System

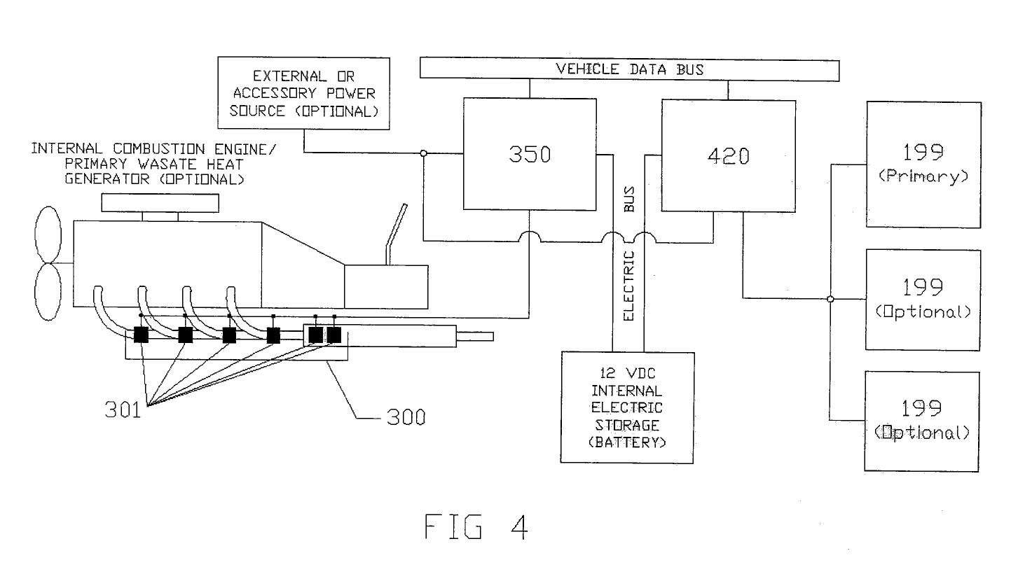

FIG. 4 illustrates one embodiment of the overall system view showing the relationship among the Cabin Environment Controller (CEC) 420 and the Power Conditioner and Controller (PCC) 350, the primary Environment Control Modules (ECM), additional optional ECMs, as well as other system components. Additional exhaust TEG array 300 elements 301 could also be added directly to the engine block 500 as engine heaters. Although the rate of cooling or heating is less than that of conventional systems, the unit can provide more than adequate cabin environmental response and control while providing significant savings in fuel and energy consumption. The unit could also be configured and programmed by the manufacturer to start cooling or heating the interior as soon as the vehicle is unlocked, by remote radio frequency (RF) trigger or by either a timer or automatic environmental control system so that cabin environment is adjusted before the occupant enters the car and the engine is started.

As shown in FIG. 4, external power/accessory power can be used to heat or cool the vehicle regardless of engine operation or car battery condition. The number and pattern of ECMs 199 can be varied based on differing cabin volumes, engine types and sizes, and environmental conditions. ECMs 199 (TEG array, fan, control, sensors, interface) can be placed at varying locations within the vehicle's interior environment to provide for zonal temperature regulation.

The figures presented above outline some embodiments of the system interfaces and overview of system operation. Due to the fact that its design can be employed in many different vehicular applications such as automobiles, light and heavy trucks, construction vehicles, and agricultural equipment the invention would have to be specifically designed and configured for the end use, but the basic principals outlined here would remain unchanged. Hybrid vehicle applications could draw the system power from the main drive battery or the alternator employed on the supplemental engine. With this configuration preheating/precooling could be accomplished without the need of large wet cell batteries or external power. Even fuel cell powered vehicles (i.e, without installed heat engines) could employ the aforementioned TEG heat pump cabin control technology as long as a viable electrical power source was able to supply power to the environmental thermoelectric array.

Additionally, external power may be employed to operate the device. If the vehicle is turned off and extended cabin temperature is required, an external source of power (e.g., AC power) can be connected to the device for continuous temperature regulation of the cabin and/or engine block without draining the battery.

Portable designs using the aforementioned TEG configurations could also be applied for retrofit and/or aftermarket uses that employ external or internal current sources for heating or cooling the cabin environment.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A system for controlling environmental conditions in an interior cabin of a vehicle, the system comprising:
a plurality of thermoelectric generator elements located spatially close together, wherein each thermoelectric generator element may be independently controlled;
an interior plenum disposed between the interior cabin and the plurality of thermoelectric generator elements, wherein the interior cabin and the thermoelectric generator elements are in fluid communication via an internal plenum apparatus;
an exterior plenum disposed between a space exterior to the cabin and the thermoelectric generator elements and thermally isolated from the interior plenum, wherein the space exterior to the cabin and the thermoelectric generator elements are in fluid communication via an external plenum apparatus and the internal and external plenums exist in one to one correspondence; and
a controller in communication with the plurality of thermoelectric generator elements, wherein the controller is capable of managing high currents for controlling the plurality of thermoelectric elements.

2. The system of claim 1, wherein the environment conditions comprises warming air, cooling air, dehumidifying air, or combinations thereof.

3. The system of claim 1, wherein the vehicle is powered at least partially by an electrical power source.

4. The system of claim 1, wherein the plurality of thermoelectric generator elements are mounted individually, mounted in a linear array, oriented and mounted in a two-dimensional contiguous array, stacked vertically, oriented and mounted in a three-dimensional contiguous array, or combinations thereof.

5. The system of claim 1, wherein each thermoelectric generator element is independently controlled to be in an off state, a warming state or a cooling state.

6. The system according to claim 1, wherein the interior plenum apparatus comprises:
at least one casing in fluid communication with the interior cabin;
at least one suction inlet;
at least one forced air output, wherein the at least one forced air outlet comprising a directionally adjustable air flow control valve or a fixed air flow outlet;
at least one thermal sensor;
at least one variable speed blower disposed to force air over the internal outermost surface of the plurality thermoelectric generator elements through at least one interior plenum outlet.

7. The system of claim 6, wherein the interior plenum apparatus further comprises:
a humidistat depending upon the location of the plurality of thermoelectric generator elements within the interior cabin.

8. The system according to claim 1, wherein the external plenum apparatus comprises:
at least one casing in fluid communication with the exterior space;
at least one air flow inlet for intake air flow;
at least one air flow outlet for exhaust air flow;
at least one thermal sensor; and
a regulated blower disposed as necessary to force air over the exposed outermost surface of the plurality of thermoelectric generator elements.

9. The system of claim 1, wherein controller further comprises:
a plurality of discrete output relay assemblies for controlling each thermoelectric generator element independently;
at least one output for controlling the plurality of thermoelectric generator elements;
at least one input comprising at least one user control line;
at least one input comprising at least one system control line;
at least one input from a high current shunt; and,
at least one method of communication between the controller and the plurality of thermoelectric generator elements.

10. The system according to claim 1, adapted to regulate interior cabin humidity, wherein a first at least a fraction of a plurality of thermoelectric generator elements surfaces within the interior plenum are put in cooling state to lower the surface temperature of the at least a fraction of a plurality of thermoelectric generator elements in gaseous contact with the air inside the plenum space to a temperature at or below the dew point to cause condensation, and putting a second at least a fraction of a plurality of thermoelectric generator elements into a heating state in an amount required to return the dehumidified plenum air at the output to a desired output temperature; and fluid control and drainage channels in the casing as required to remove liquid condensate from the interior plenum space.

11. The system according to claim 1, adapted to permit conditioning of the interior cabin at or before vehicle start-up to appropriate environmental conditions and directed air flows based upon a user's desired operating mode of maintaining a selected cabin temperature range and environmental state, wherein the power used is provided through an electrical bus of the vehicle or an external source.

12. The system of claim 11, wherein the appropriate environmental conditions and directed air flows are inputted using pre-programmed instructions, learned operation and usage patterns, on-demand or combinations thereof.

13. The system according to claim 1, wherein the system is portable.

14. The system of claim 1, wherein the system is retrofitted to the vehicle.

15. A system for generating supplemental electric current by harvesting waste heat from a an exhaust gas stream generated by at least one engine of a vehicle, the system comprising:
a plurality of thermoelectric generator elements with a first outermost surface of each thermoelectric generator element affixed in direct or proximal contact to a waste heat source and a second outermost surface of each thermoelectric generator element is thermally isolated from the first side and in thermal communication with outside air and with the second side of the mounted the plurality of thermoelectric generator elements;
a controller in communication with the plurality of thermoelectric generator elements, wherein the controller conditions and controls the generated current to regulate the power prior to distribution via a primary electrical bus of the vehicle.

16. The system of claim 15, wherein the waste heat source comprises an engine block, an exhaust manifold, an exhaust pipe, an acoustic muffling device, or combinations thereof.

17. The system of claim 15, wherein the outside air is developed by capturing ram air formed by the vehicle's forward motion, by an electric blower, or by combinations thereof.

18. The system of 15, wherein the first outermost surface of each thermoelectric generator element in thermal communication with the vehicle component or a directed flow of outside air and the second outermost surface of each thermoelectric generator element thermally isolated from the first side and in thermal communication with a liquefied fuel source for generating current conditioned and controlled in a manner to regulate the power prior to distribution via the vehicle's primary electrical bus.

19. The system according to claim 15, wherein the controller is capable of managing high currents to condition the collective electric output of the thermoelectric generator elements and to control supplemental electrical power delivery.

20. The system according to claim 15, wherein the controller comprises:
at least one high current output in electrical series with an isolating diode block and connected to the vehicle's primary electrical bus/battery through a circuit protection device;
at least one high current, bi-directional input/output line in electrical contact with one plurality of thermoelectric generator elements wherein each thermoelectric generator element has at least one input from a high current shunt for measuring total current generated by the plurality of thermoelectric generator elements;
at least one output connected to control a relay in electrical contact with the terminating thermoelectric generator element of the array and configured to “make or break” an electrical circuit to the vehicle's ground to electrically isolate the plurality of thermoelectric generator elements;
a plurality of control lines for the operation of the devices used for blowing air &/or flowing engine coolant or fuel to cause thermal transfer towards the outermost second surfaces of the thermoelectric generator elements;
the user's desired inputs;
controller system inputs; and,
at least one method of communication between the controller and the plurality of thermoelectric generator elements.

21. The system of claim 15, wherein the system is adapted to warm vehicle engine components and internal fluids by the application of a regulated electrical current to at least one of the plurality of thermoelectric generator elements wherein the outermost surface of the activated thermoelectric generator elements in direct or proximal contact with the vehicle's component surfaces becomes the first side such that heat is conducted into the component, or a thermoelectric generator element or a plurality of thermoelectric generator elements such that the first side of the plurality of thermoelectric generator elements is in actual or proximal contact with a vehicle's fluid (lubricant or fuel) or fluid reservoir(s) such that heat is conducted into the fluid.

22. The system of claim 21, wherein the power used to drive the plurality of thermoelectric generator elements is provided through the vehicle's electrical bus by generated supplemental power, the vehicle's primary electrical storage device, or by an external source.

23. A method for controlling environmental conditions in an interior cabin of a vehicle, the method comprising:
providing a plurality of thermoelectric generator elements spatially close together, wherein each thermoelectric generator element may be independently controlled;
disposing an internal plenum between the interior cabin and the plurality of thermoelectric generator elements, wherein the interior cabin and the thermoelectric generator elements are in fluid communication via an internal plenum apparatus;
disposing an external plenum between a space exterior to the cabin and the thermoelectric generator elements and thermally isolating the external plenum from the interior plenum, wherein the space exterior to the interior cabin and the thermoelectric generator elements are in fluid communication via an external plenum apparatus and the internal and external plenums exist in one to one correspondence; and
controlling the plurality of thermoelectric generator elements with a controller, wherein the controller is capable of managing high currents.

24. A method for generating supplemental electric current by harvesting waste heat from a an exhaust gas stream generated by at least one engine of a vehicle, the method comprising:
providing a plurality of thermoelectric generator elements with a first outermost surface of each thermoelectric generator element affixed in direct or proximal contact to a waste heat source and a second outermost surface of each thermoelectric generator element thermally isolated from the first side and in thermal communication with outside air and with the second side of the mounted the plurality of thermoelectric generator elements;
controlling the plurality of thermoelectric generator elements with a controller, wherein the controller conditions and controls the generated current to regulate the power prior to distribution via a primary electrical bus of the vehicle.
